(19) United States
(12) Patent Application Publication
(10) Pub. No.: US 2009/0265928 A1
(43) Pub. Date: Oct. 29, 2009

(54) Circuit board and manufacturing method thereof

(76) Inventor: Jong-Bo SHIM, Cheonan-si (KR)

Correspondence Address: HARNESS, DICKEY & PIERCE, P.L.C., P.O. BOX 8910, RESTON, VA, 20195, US

(21) Appl. No.: 12/458,088

(22) Filed: Jun. 30, 2009

Related U.S. Application Data
(62) Division of application No. 11/342,845, filed on Jan. 31, 2006.

(30) Foreign Application Priority Data
Aug. 9, 2005 (KR) 2005-72882

(51) Int. Cl. H05K 3/30

(52) U.S. Cl. 29/832

(57) ABSTRACT

A circuit board may have a metal land supporting a pillar. The pillar may be fabricated by half-etching the metal land. An insulating layer may be provided on the circuit board so that the pillar of the metal land may be exposed through the insulating layer.

### PRIORITY STATEMENT

This application is a divisional of U.S. patent application Ser. No. 11/342,845 filed on Jan. 31, 2006, which claims priority under 35 U.S.C. § 119 from Korean Patent Application No. 2005-72882 filed Aug. 9, 2005, the contents of which are incorporated by reference in their entirety.

### BACKGROUND

1. Field of the Invention

Example embodiments of the present invention relate to a circuit board and a method for manufacturing the same.

2. Description of the Related Art

Ball grid array (BGA) packages may be employed to meet various semiconductor package requirements.

As shown in FIG. 1, a conventional BGA package 100 may include a printed circuit board (PCB) 110. The PCB may include a board body 111, a semiconductor chip 120 may be mounted on the PCB 110, bonding wires 130 may connect the PCB 110 to the semiconductor chip 120, and an encapsulant 140 may seal the semiconductor chip 120 and the bonding wires 130. The board body 111 may have a lower surface 111b that may support metal lands 112. External connection terminals, for example solder bumps 150, may be provided on the metal lands 112.

Although the BGA package 100 may generally provide acceptable performance, it is not without shortcomings. For example, when the pitch between the solder bumps 150 is about 0.5 mm, the height of the solder bump 150 may be about 0.24 mm, which may form about 25% of the package thickness. This may result in an increased thickness of the BGA package 100.

Metal lands (instead of solder bumps) may be implemented as external connection terminals. FIG. 2 shows a land grid array package implementing metal lands.

As shown in FIG. 2, the land grid array package 200 may have metal lands 212. In all other respects, the land grid array package 200 may have the same structure as the BGA package 100 shown in FIG. 1. The land grid array package 200 may comprise a PCB 210. The PCB 210 may include a board body 211. The board body 211 may have a lower surface 211b that may support the metal lands 212. To mount the land grid array package 200 on a mother board, the metal lands 212 may be bonded to board lands of the mother board with a solder paste interposed therebetween. The land grid array package 200 may not implement the solder bumps 150 of FIG. 1.

In the land grid array package 200, an insulating layer 260, which may protect the metal lands 212, may have a greater height than that of the metal lands 212, which may cause (for example) faults on mounting the land grid array package 200 on the mother board. Further, cracks may result from (for example) the difference between the coefficient of thermal expansion of the land grid array package 200 and that of the mother board, thereby reducing the electrical connection reliability between the land grid array package 200 and the mother board.

### SUMMARY

According to an example, non-limiting embodiment, a circuit board may include a board body having an upper surface and a lower surface. A first circuit pattern may be provided on the upper surface of the board body. The first circuit pattern may have a board pad. A second circuit pattern may be provided on the lower surface of the board body. The second circuit pattern may have a metal land. The metal land may support a pillar. A through electrode may connect the first circuit pattern to the second circuit pattern. A first insulating layer may be provided on the first circuit pattern. The first insulating layer may expose the board pad. A second insulating layer may be provided on the second circuit pattern. The second insulating layer may expose the pillar.

According to another example, non-limiting embodiment, a method for manufacturing a circuit board may involve providing a resin layer having a bottom surface and a metal plate provided on the bottom surface of the resin layer. The metal plate may be etched to form a pillar. The metal plate may be patterned to form a metal land having the pillar. An insulating layer may be provided on the bottom surface of the resin layer exposing a portion of the metal land.

According to another example, non-limiting embodiment, a method for manufacturing a circuit board may involve providing a resin layer having a bottom surface and a metal plate provided on the bottom surface of the resin layer. The metal plate may be patterned to form a metal land. An insulating layer may be provided on the bottom surface of the resin layer to cover the metal land. The metal land may be etched to form a pillar on the metal land.

According to another example, non-limiting embodiment, a circuit board may include a body having an upper surface with a chip mounting area. The body may have a lower surface that may support a circuit pattern having a conductive land. The conductive land may include a base portion and a protruding structure that extends from the base portion. An insulating layer may be provided on the circuit pattern. The insulating layer may expose the protruding structure.

### BRIEF DESCRIPTION OF THE DRAWINGS

Example, non-limiting embodiments of the present invention will be readily understood with reference to the following detailed description thereof provided in conjunction with the accompanying drawings, wherein like reference numerals designate like structural elements.

FIG. 1 is a schematic cross-sectional view of a conventional ball grid array semiconductor package.

FIG. 2 is a schematic cross-sectional view of a conventional land grid array semiconductor package.

FIG. 3A is a cross-sectional view of a circuit board in accordance with an example, non-limiting embodiment of the present invention.

FIG. 3B is a plan view of FIG. 3A.

FIG. 3C is a cross-sectional view of a circuit board in accordance with another example, non-limiting embodiment of the present invention.

FIGS. 4A through 4F are cross-sectional views of a process that may be implemented to manufacture a circuit board in accordance with an example, non-limiting embodiment of the present invention.

FIGS. 5A through 5F are cross-sectional views of a process that may be implemented to manufacture a circuit board in accordance with another example, non-limiting embodiment of the present invention.

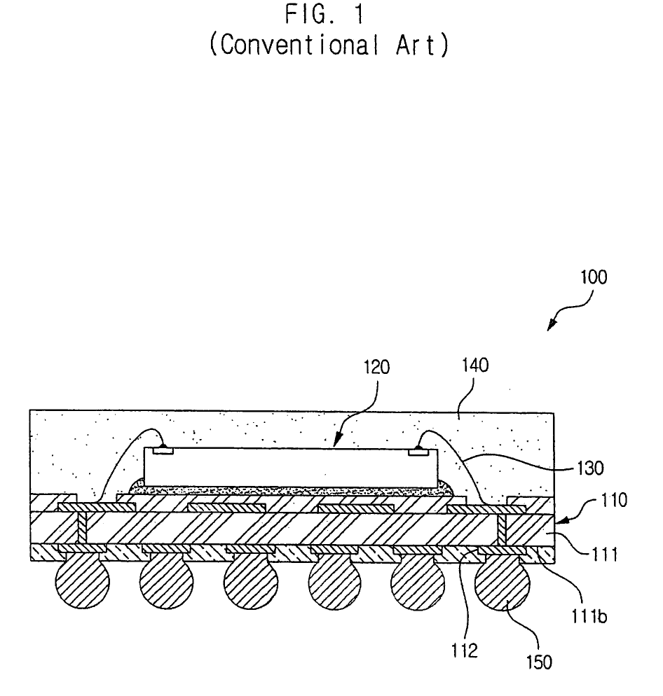

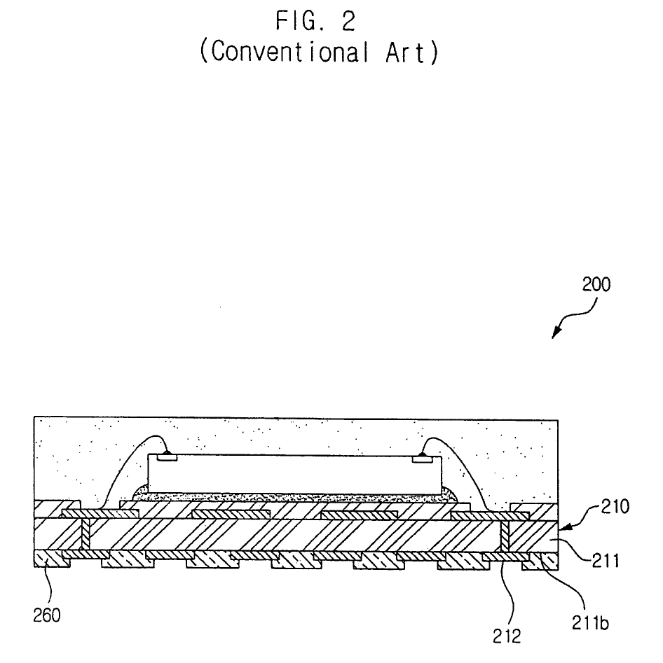

The drawings are provided for illustrative purposes only and are not drawn to scale. The spatial relationships and relative sizing of the elements illustrated in the various embodiments may be reduced, expanded and/or rearranged to improve the clarity of the figure with respect to the corresponding description. The figures, therefore, should not be interpreted as accurately reflecting the relative sizing or positioning of the corresponding structural elements that could be encompassed by an actual device manufactured according to example embodiments of the invention.

### DETAILED DESCRIPTION OF EXAMPLE, NON-LIMITING EMBODIMENTS

Example, non-limiting embodiments of the present invention will be described with reference to the accompanying drawings. This invention may, however, be embodied in many different forms and should not be construed as limited to example embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

Well-known structures and processes are not described or illustrated in detail to avoid obscuring the present invention.

An element is considered as being mounted (or provided) “on” another element when mounted or provided) either directly on the referenced element or mounted (or provided) on other elements overlaying the referenced element. Throughout this disclosure, spatial terms such as “upper,” “lower,” “above” and “below” (for example) are used for convenience in describing various elements or portions or regions of the elements as shown in the figures. These terms do not, however, require that the structure be maintained in any particular orientation.

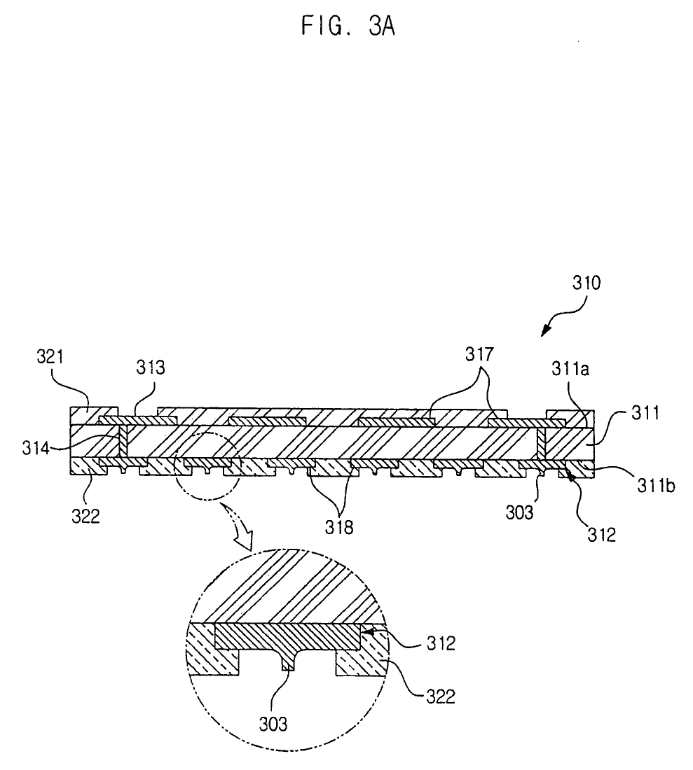

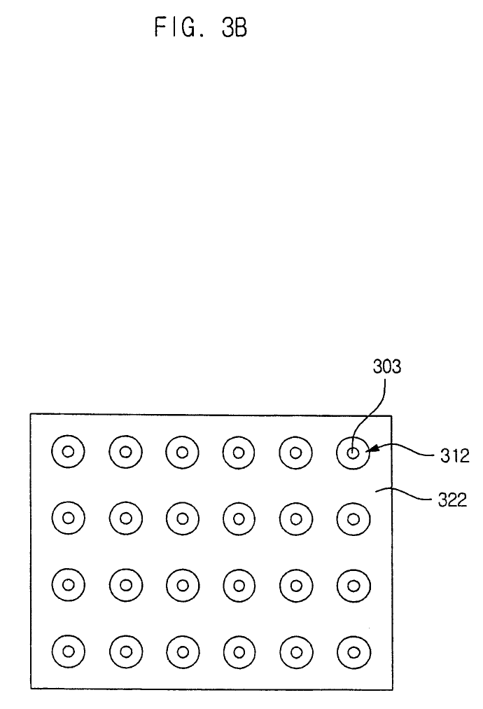

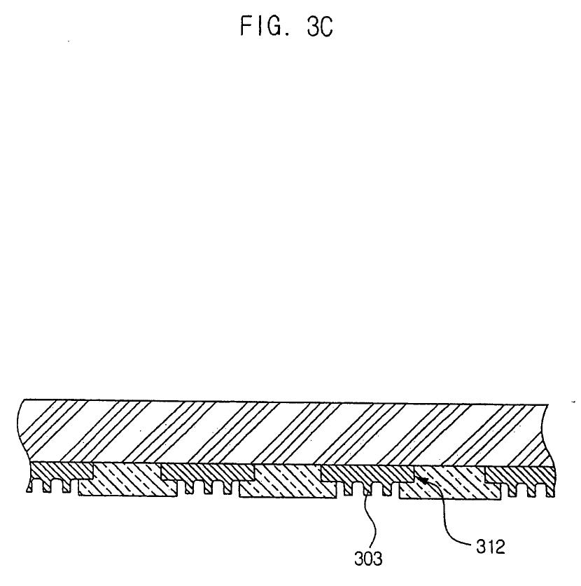

FIG. 3A is a cross-sectional view of a circuit board 310 in accordance with an example embodiment of the present invention. FIG. 3B is a plan view of FIG. 3A.

Referring to FIGS. 3A and 3B, the circuit board 310 may be a PCB, for example. The PCB 310 may include a board body 311 that may have an upper surface 311a and a lower surface 311b, a first circuit pattern 317, a second circuit pattern 318, a through electrode 314, a first insulating layer 321 and a second insulating layer 322. The first circuit pattern 317 may be provided on the upper surface 311a of the board body 311. The first circuit pattern 317 may have a board pad 313. The second circuit pattern 318 may be provided on the lower surface 311b of the board body 311. The second circuit pattern 318 may have a conductive land 312. In this example embodiment, the conductive land 312 may be fabricated from a metal. The through electrode 314 may connect the first circuit pattern 317 to the second circuit pattern 318. The first insulating layer 321 may be provided on the first circuit pattern 317. A portion of the board pad 313 may be exposed through the first insulating layer 321. The second insulating layer 322 may be provided on the second circuit pattern 318. A portion of the metal land 312 may be exposed through the second insulating layer 322.

The metal land 312 may have a base portion and a protruding structure that extends from the base portion in a direction away from lower surface 311b. By way of example only, the structure may be a pillar 303 that may extend vertically from the base portion. The pillar 303 and the base portion may be of an integral, one-piece construction. The pillar 303 may extend from a center region of the base portion. The pillar 303 may be fabricated by etching (e.g., half-etching) the metal land 312. The metal land 312 may have a solder mask defined (SMD) type structure in which the peripheral region of the metal land may be covered by the second insulating layer 322. Alternatively, the metal land 312 may have a non-solder mask defined (NSMD) type structure in which the peripheral region of the metal land may be exposed through the second insulating layer 322. By way of example only, the height of the pillar 303 from the lower surface 311b of the board body 311 may be equal to or less than that of the second insulating layer 322.

A Ni/Au alloy layer may be provided on the metal land 312. The Ni/Au alloy layer may improve the connection reliability of the printed circuit board 310 to an external device (such as a mother board, for example). In alternative embodiments, a Ni layer may be provided on the metal land 312 and an Au layer may be provided on the Ni layer.

The pillar 303 may increase the bonding strength between the metal land 312 and a board land of a mother board. The pillar 303 may also reduce the likelihood that cracks may occur at the interface between the metal land 312 and a board land, due to the difference between the coefficient of thermal expansion of a semiconductor package and that of a mother board, for example. The resultant semiconductor package implementing the circuit board 310 may have improved connection reliability between the metal land 312 and a board land, thereby improving connection reliability between the semiconductor package and a mother board.

FIG. 3C is a cross-sectional view of a circuit board in accordance with another example, non-limiting embodiment of the present invention.

Referring to FIG. 3C, the circuit board may be a PCB, for example. The PCB may have a plurality of structures (e.g., pillars 303) that extend from the base portion of a metal land 312. The pillars 303 of this example embodiment may be fabricated in the same manner as in the previous example embodiment. However, a plurality of pillars 303 may be fabricated by changing the pattern of a mask that may be implemented in an etching process. By virtue of the plurality of pillars 303, the interface between the metal land 312 and a board land may be increased, thus reducing the likelihood that cracks may occur at the interface between the metal land 312 and the board land.

An example, non-limiting method that may be implemented to manufacture a circuit board is described below.

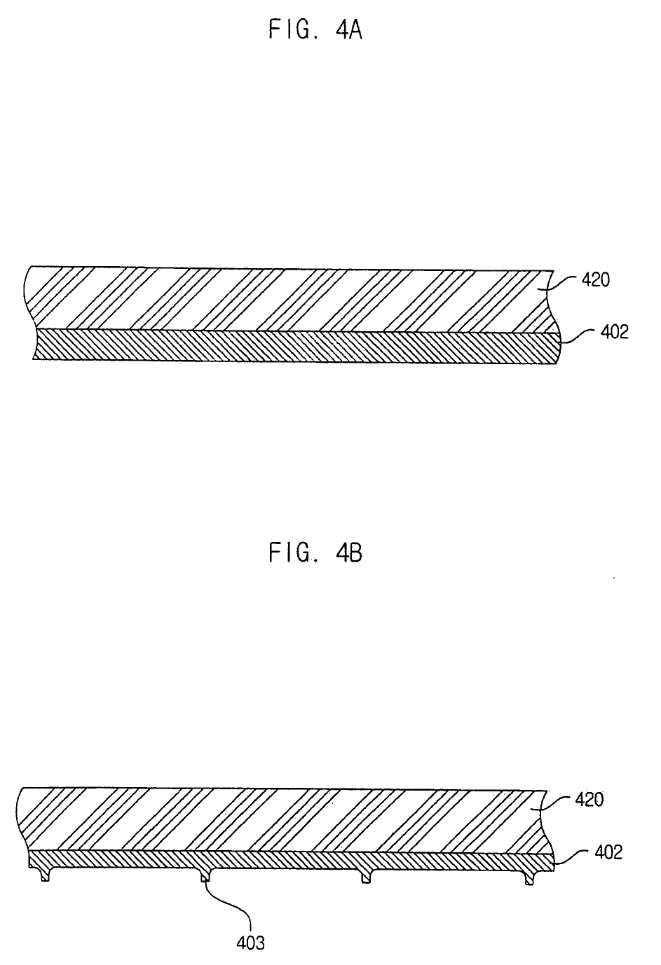

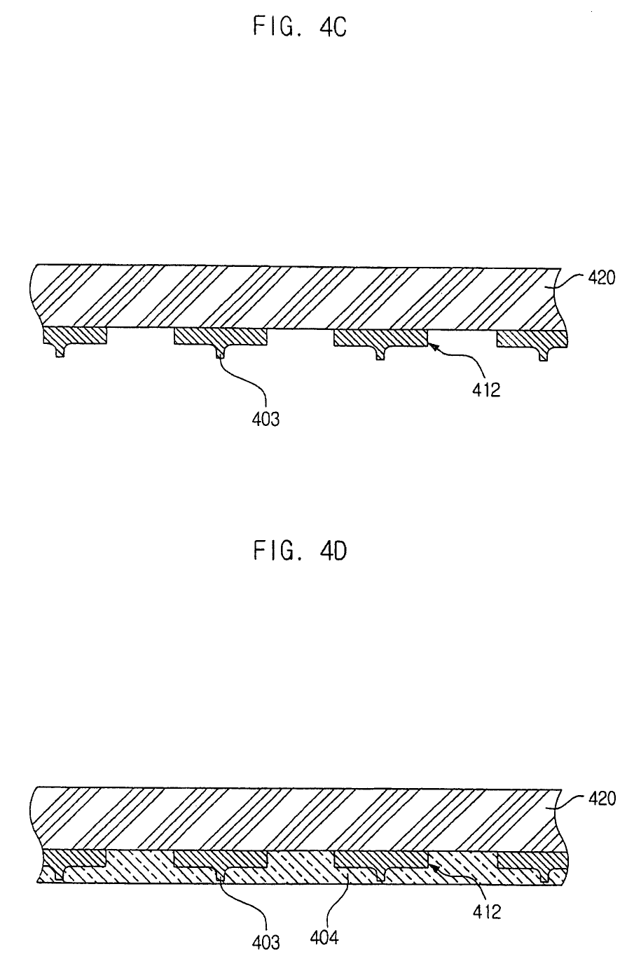

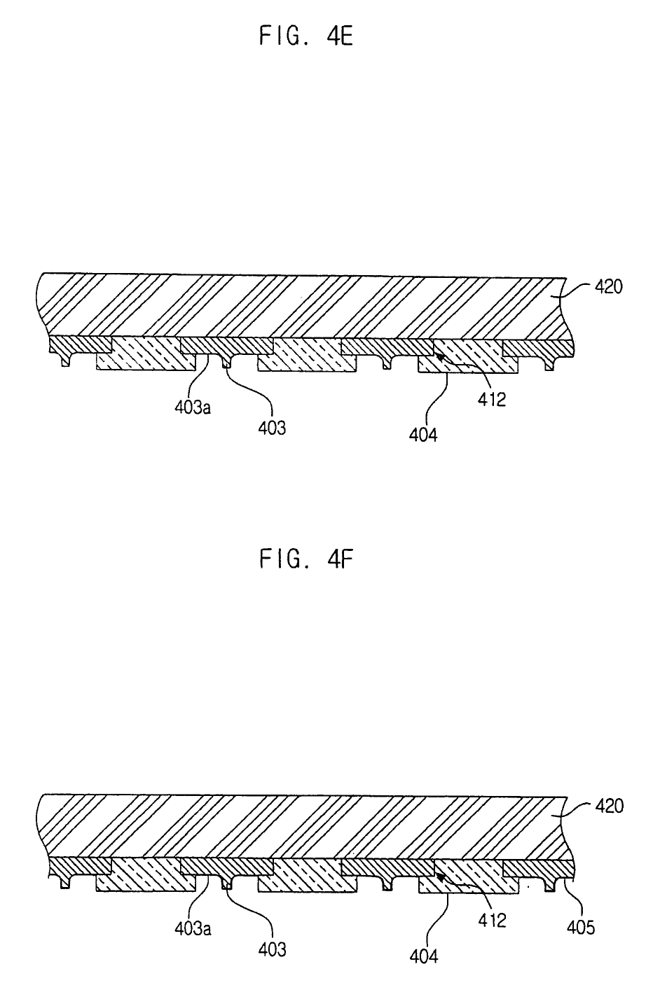

FIGS. 4A through 4F are cross-sectional views of a manufacturing process for a printed circuit board in accordance with an example, non-limiting embodiment of the present invention.

Referring to FIG. 4A, the method may involve providing a resin layer 420 and a metal plate 402. The resin layer 420 may form a core of a printed circuit board and have a bottom surface. The metal plate 402 may be provided on the bottom surface of the resin layer 420. By way of example only, the metal plate 402 may be a Cu film. The metal plate 402 may be attached to the resin layer 420 through a thermocompression method and/or using an adhesive, for example. By way of example only, the metal plate 402 may have a thickness of 35 μm, 18 μm, or 12 μm. By way of example only, the resin layer 420 may be fabricated from a dielectric material, such as photosolder resist (PSR), glass/epoxy (e.g., flame resistant-4 (FR-4)) resin, bismaleimide triazine (BT) resin and/or Aramid resin, and the resin layer 420 may have a thickness of between 25 μm and 100 μm.

Referring to FIG. 4B, the metal plate 402 may be etched to form a pillar 403. In this example embodiment, the metal plate 402 may be half-etched. For example, a first dry film may be provided on the metal plate 402. The first dry film may be patterned according to the desired quantity and the shape of the pillar 403. The first dry film may include photoresist and the patterning process may use a photolithographic process. The metal plate 402 may be half-etched using an etching solution. By way of example only, the etching solution may include a ferric chloride leaching, a cupric chloride leaching and/or an alkali aqueous solution or a sulfate hydrogen peroxide solution containing ammonium complex ion as a main component. The first dry film may be removed using a removing solution.

Referring to FIG. 4C, the half-etched metal plate 402 may be patterned to form a metal land 412. For example, a second dry film may be applied to the metal plate 402 and be patterned. A portion of the metal plate 402 exposed through the second dry film may be wet etched. A metal land 412 may be formed on the bottom surface of the resin layer 420 corresponding to the pattern of the second dry film. The etching solution used in the wet etching process may be the same as the etching solution used in forming the pillar 403. In alternative embodiments, different etching solutions may be suitably implemented in the various etching processes.

Referring to FIG. 4D, a second insulating layer 404 may be provided on the bottom surface of the resin layer 420. By way of example only, the second insulating layer 404 may be fabricated from one of photosolder resist (PSR), BT resin and FR-4 resin. In the case of PSR, the second insulating layer 404 may be fabricated using a screen printing method, for example.

Referring to FIG. 4E, the second insulating layer 404 may be patterned such that a portion 403a of the base of the metal land 412 and the pillar 403 may be exposed. If the second insulating layer 404 is fabricated from PSR, the patterning process may use a photolithographic process, for example.

Referring to FIG. 4F, a Ni/Au alloy layer 405 may be provided on the portion 403a of the metal land 412 that may be exposed through the second insulating layer 404. The Ni/Au alloy layer 405 may be fabricated using a sputtering method and/or a plating method, for example. In alternative embodiments, a Ni layer may be provided on the exposed portion 403a of the metal land 412 including the pillar 403 and then an Au layer may be provided on the Ni layer.

In alternative embodiments, the method may have variations and/or modifications in the procedural order.

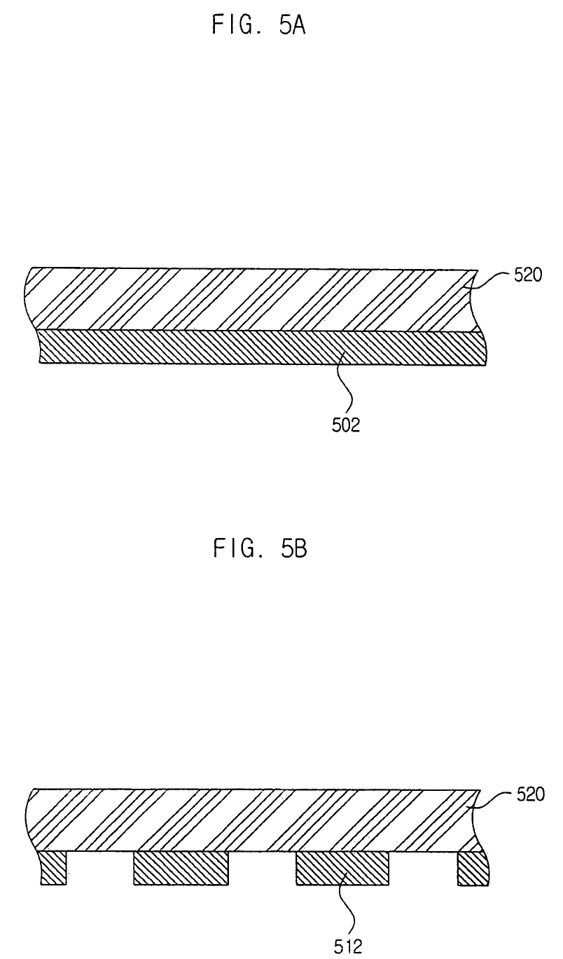

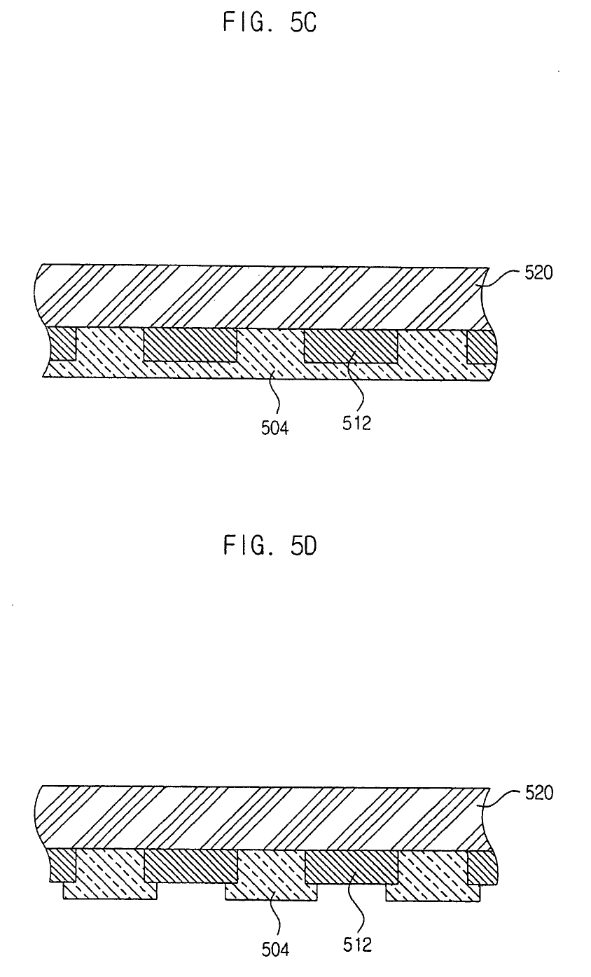

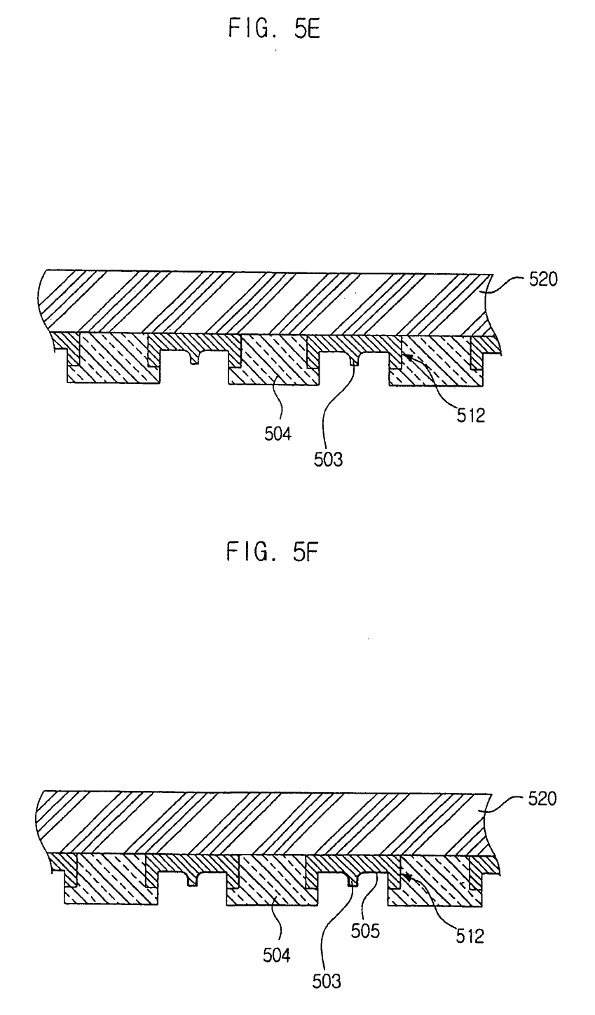

FIGS. 5A through 5F are cross-sectional views of a manufacturing process for a printed circuit board in accordance with another example, non-limiting embodiment of the present invention.

Referring to FIG. 5A, a metal plate 502 may be provided on the bottom surface of a resin layer 520.

Referring to FIG. 5B, the metal plate 502 may be patterned to form a metal land 512.

Referring to FIG. 5C, a second insulating layer 504 may be provided on the bottom surface of the resin layer 520.

Referring to FIG. 5D, the second insulating layer 504 may be patterned such that a portion of the metal land 512 may be exposed.

Referring to FIG. 5E, the exposed portion of the metal land 512 may be half-etched (for example) to form a pillar 503 on the metal land 512.

Referring to FIG. 5F, a Ni/Au alloy layer 505 may be provided on the exposed portion of the metal land 512 including the pillar 503.

In this embodiment, the metal land 512 may be formed and the metal plate 502 may maintain its initial thickness. Accordingly, the thickness of the metal land 512 may be greater than that of the previous example embodiment. Further, the likelihood of an irregular thickness of the metal land 512 may be reduced.

Example, non-limiting embodiments have been particularly shown and described. It will be understood by those skilled in the art that various changes in form and details may be made therein without departing from the spirit and scope of the invention as defined by the appended claims.

For example, the printed circuit board may be implemented in a variety of semiconductor packages. The printed circuit board may be implemented in a multi-stack package including a plurality of semiconductor packages. When an upper package is stacked on a lower package, the metal land may electrically connect the upper package to the lower package. In this way, the resultant multi-stack package may be thinner than a multi-stack package using solder bumps.

By way of example only, the pillar may be fabricated while forming the metal land, thus resulting in a simple manufacturing process of a printed circuit board.

In the example embodiments, the pillar may have a circular cross sectional shape. In alternative embodiments, the pillar may have any geometric cross sectional shape. In the example embodiment, the pillar may have a uniform width. In alternative embodiments, the width of the pillar may vary. For example, the pillar may taper away from the base of the metal land. In the example embodiments, a given board body may have pillars of a same shape. In alternative embodiments, a given board body may have pillars of different shapes.

The pillar may reduce the likelihood that cracks may occur at the interface between a semiconductor package and a mother board due to the difference between the coefficient of thermal expansion of a semiconductor package and that of a mother board, thereby improving the solder joint reliability of the semiconductor package. The mounting faults of a semiconductor package may also be reduced.

Further, the thickness of a semiconductor package using the printed circuit board may be reduced.

What is claimed is:

1. A method for manufacturing a circuit board comprising:
providing a resin layer having a bottom surface and a metal plate provided on the bottom surface of the resin layer;
etching the metal plate to form a pillar; and
patterning the metal plate to form a metal land having the pillar.

2. The method of claim 1, further comprising:
providing an insulating layer on the bottom surface of the resin layer exposing a portion of the metal land.

3. The method of claim 1, wherein the etching includes forming a dry film on the metal plate, patterning the dry film, half-etching the metal plate, and removing the dry film.

4. The method of claim 1, wherein the etching uses a wet etching method.

5. The method of claim 1, further comprising plating a Ni/Au alloy layer on the metal land.

6. The method of claim 1, further comprising plating a Ni layer on the metal land, and plating an Au layer on the Ni layer.

7. A method for manufacturing a circuit board comprising:
providing a resin layer having a bottom surface and a metal plate provided on the bottom surface of the resin layer;
patterning the metal plate to form a metal land; and
etching the metal land to form a pillar on the metal land.

8. The method of claim 7, further comprising:
providing an insulating layer on the bottom surface of the resin layer to cover the metal land; and

9. The method of claim 7, wherein the etching uses a wet etching method.

10. The method of claim 7, further comprising plating a Ni/Au alloy layer on the metal land.

11. The method of claim 7, further comprising plating a Ni layer on the metal land, and plating an Au layer on the Ni layer.
